(19) United States
(12) Patent Application Publication
(10) Pub. No.: US 2014/0240935 A1
(43) Pub. Date: Aug. 28, 2014

(54) ELECTRONIC DEVICE WITH DISPLAY

(71) Applicant: HON HAI PRECISION INDUSTRY CO., LTD., New Taipei (TW)

(72) Inventors: CHIA-MING CHANG, New Taipei (TW); YI-CHENG KUO, New Taipei (TW)

(73) Assignee: HON HAI PRECISION INDUSTRY CO., LTD., New Taipei (TW)

(21) Appl. No.: 14/160,793

(22) Filed: Jan. 22, 2014

(30) Foreign Application Priority Data
Feb. 26, 2013 (TW) 102106617

(51) Int. Cl. H05K 5/03; H05K 5/00

(52) U.S. Cl. CPC H05K 5/03; H05K 5/0017
USPC 361/752

(57) ABSTRACT

An electronic device includes a display. The display includes a cover, a protection module, and a display panel. The protection module includes an outer frame, a flange, and a supporting strip. The outer frame is secured to the cover. The flange is secured to a first side of the outer frame. The supporting strip extends out of a second side of the outer frame and is located between the cover and the display panel, to protect the display panel from external impact. The flange and the supporting strip are integrally formed with the outer frame.

### BACKGROUND

1. Technical Field

The present disclosure relates to electronic devices, and particularly to an electronic device with a display.

2. Description of Related Art

An electronic device with a display, such as a notebook computer, may comprise additional components to protect the display from external impact. However, in assembly, the additional components need to be secured to the display individually, which increases a cost of assembly. Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of one embodiment of a display of an electronic device.

FIG. 2 is an exploded, isometric view of a protection module of the electronic device of FIG. 1.

FIG. 3 is an enlarged view of a circled portion III of FIG. 1.

FIG. 4 is an assembled, isometric view of the electronic device of FIG. 1.

FIG. 5 is an enlarged view of a circled portion V of FIG. 4.

FIG. 6 is similar to FIG. 4, but viewed from a different aspect.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

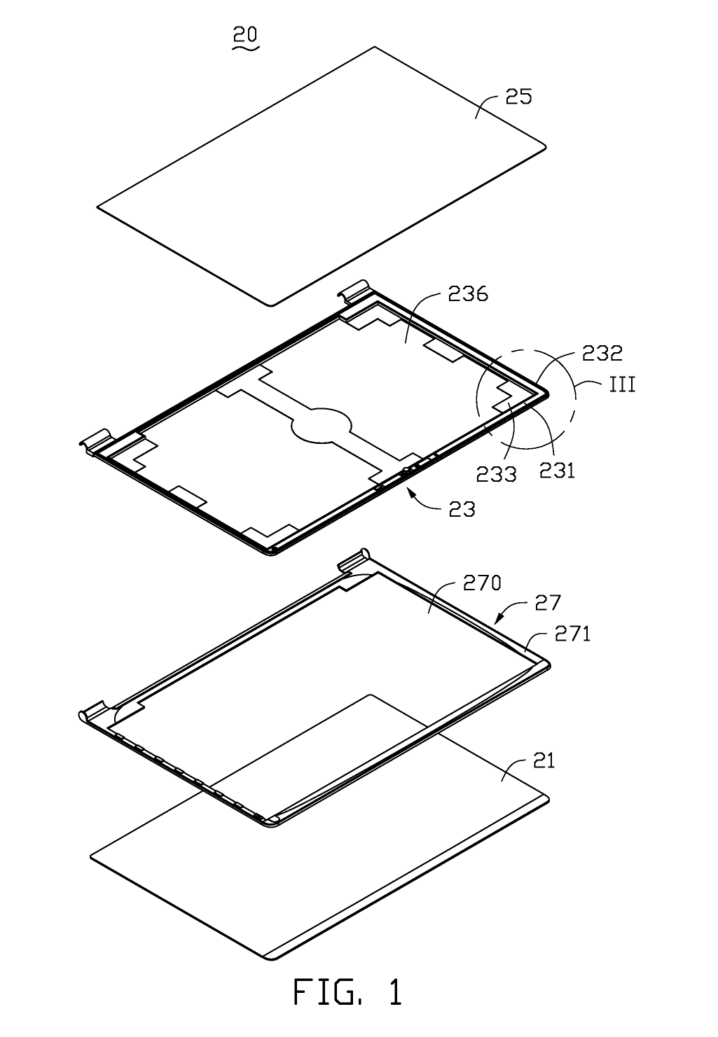

FIG. 1 shows one embodiment of a display 20 of an electronic device. The display 20 comprises a cover 21, a protection module 23, a display panel 25, and an installation frame 27.

The cover 21 is installed in the installation frame 27. In the illustrated embodiment, the installation frame 27 is substantially rectangular and cooperatively formed by four installation strips 271. The installation frame 27 defines a receiving slot 270. A thickness of the cover 21 is smaller than a thickness of each installation strip 271.

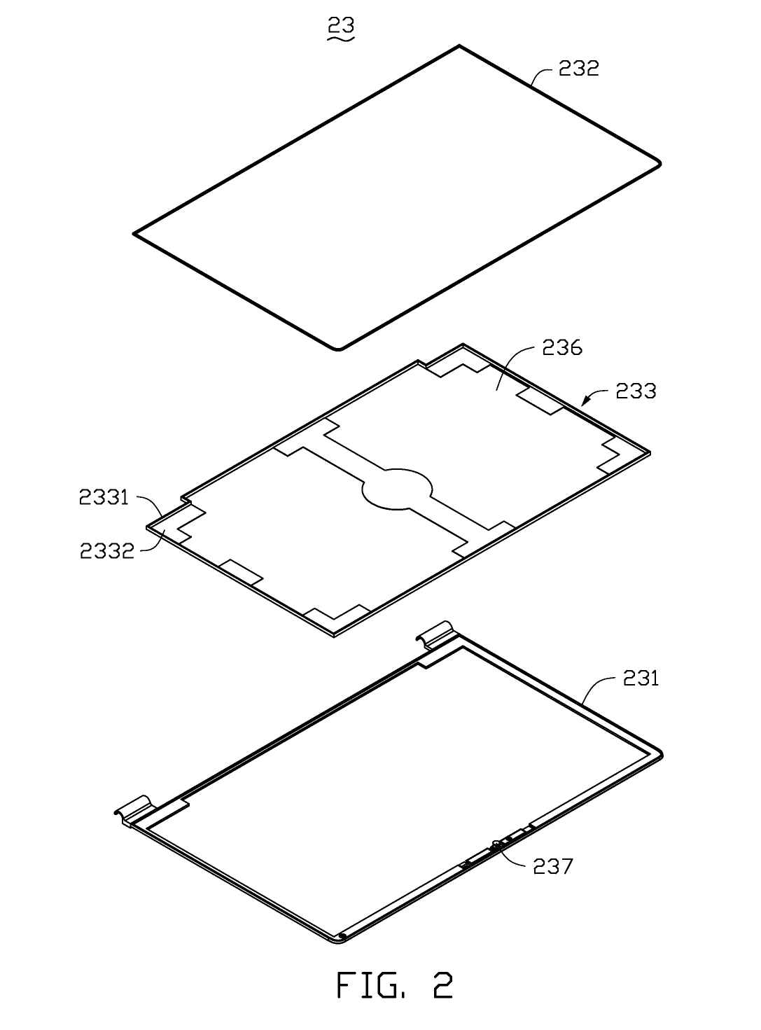

FIG. 2 shows that the protection module 23 comprises an outer frame 231, a first protection member 232, and a second protection member 233. The protection module 23 protects the display panel 25 from external impact.

In the illustrated embodiment, the outer frame 231 is substantially rectangular and is secured to the installation frame 27. A camera module 237 is secured to the outer frame 231.

In the illustrated embodiment, the first protection member 232 is substantially rectangular and is received in the outer frame 231. When the first protection member 232 is received in the outer frame 231, the first protection member 232 protrudes from a first side of the outer frame 231.

The second protection member 233 is also received in the outer frame 231. The second protection member 233 comprises a flange 2331 protruding around a peripheral edge thereof, and a plurality of supporting strips 2332. When the second protection member 233 is received in the outer frame 231, the flange 2331 abuts inner surfaces of the outer frame 231. The supporting strips 2332 extend substantially perpendicularly from a bottom edge of the flange 2331. A height of the flange 2331 is greater than a height of the outer frame 231, so that the flanges 2331 protrude from a second side of the outer frame 231 opposite to the first side of the outer frame 231. The second protection member 233 defines a receiving space 236 bound by the flange 2331.

In one embodiment, the outer frame 231 is made of plastic, and the first protection member 232 and the second protection member 233 are made of flexible glue. In one embodiment, the outer frame 231 is integrally formed with the first protection member 232 and the second protection member 233 by double-shot molding.

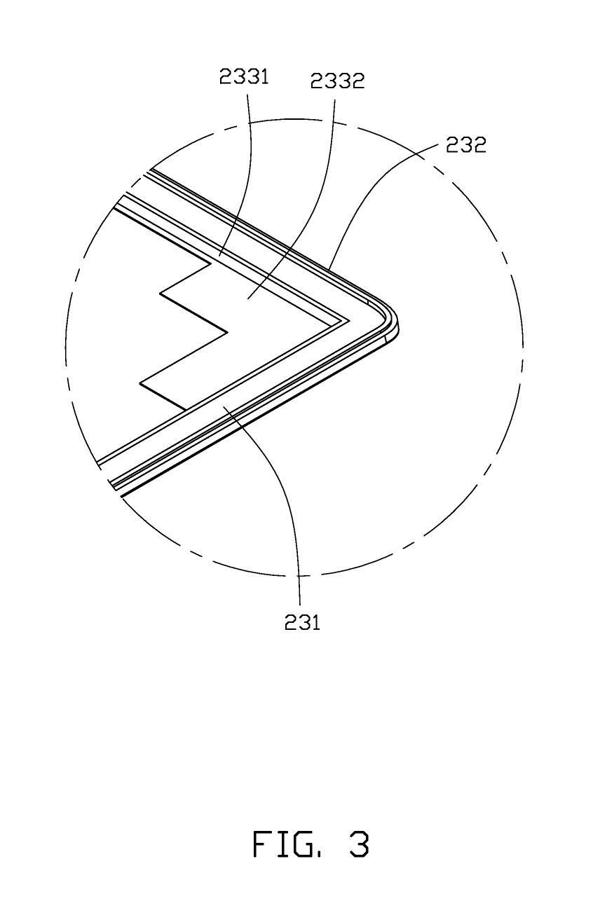

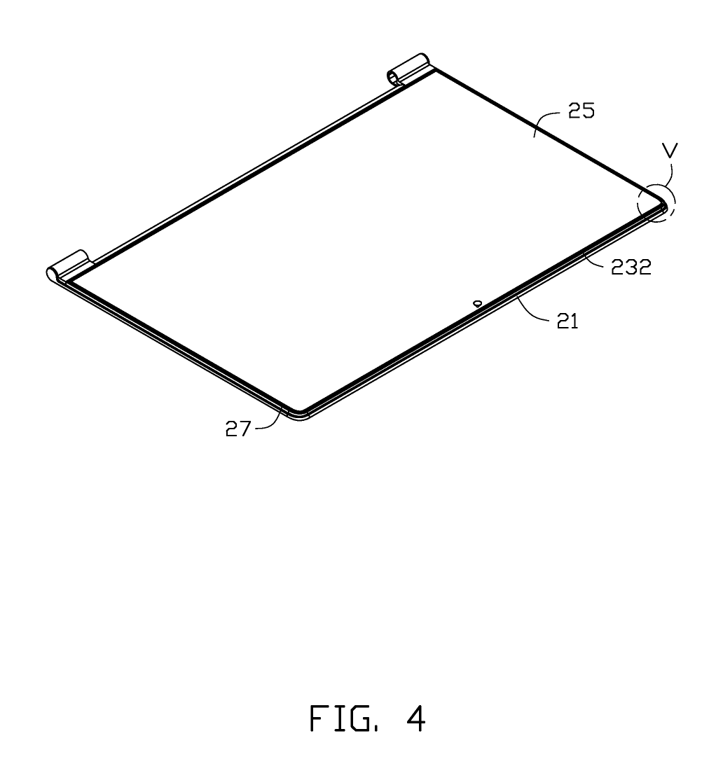

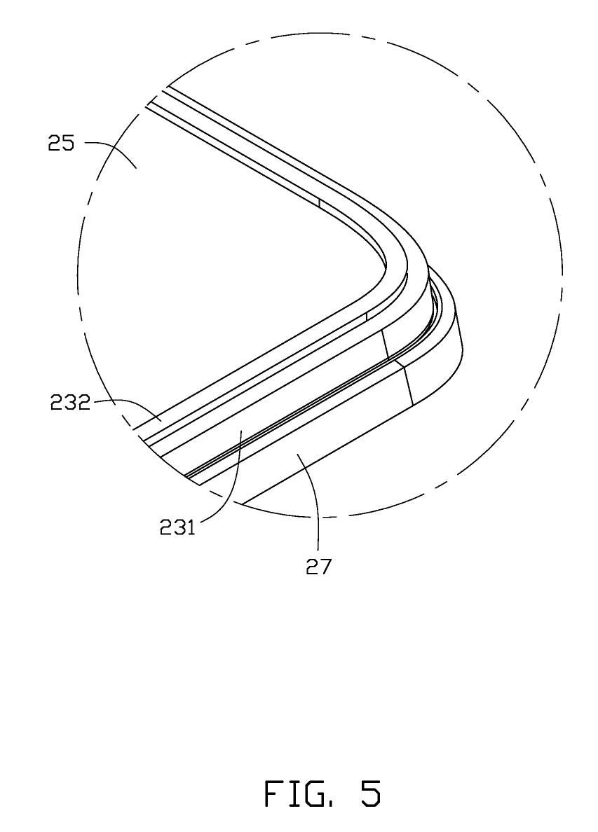

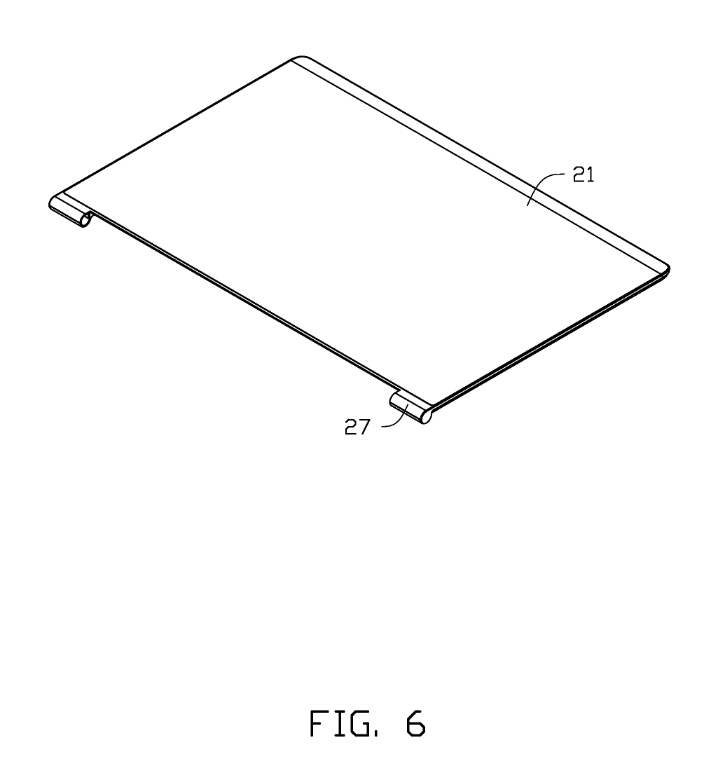

FIGS. 3-6 show that in assembly, the cover 21 is secured to the installation frame 27 and covers the receiving slot 270. The outer frame 231 is secured to the installation frame 27. The second protection member 233 is received in the receiving slot 270, and the display panel 25 is received in the receiving space 236. The cover 21 holds the protection module 23, side surfaces of the display panel 25 abut the flange 2331, and a bottom surface of the display panel 25 is held by the supporting strips 2332. The flanges 2331 and the supporting strips 2332 protect the side surfaces and the bottom surface of the display panel 25 from external impact.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and the arrangement of parts within the principles of the disclosure, to the full extent indicated by the broad general meaning of the terms in which the appended claims are expressed.

What is claimed is:

1. An electronic device, comprising:
a display comprising:
a cover;
a protection module comprising an outer frame, a first protection member, and a second protection member; and
a display panel;
wherein the outer frame is secured to the cover; the first protection member is secured to a first side of the outer frame; the second protection member extends out of a second side of the outer frame and is located between the cover and the display panel, to prevent the display panel from being hit by the cover; and the first protection member and the second protection member are integrated with the outer frame.

2. The electronic device of claim 1, wherein each of the first protection member and the second protection member is made of flexible glue.

3. The electronic device of claim 2, wherein the outer frame is made of plastic, and the first protection member is integrated with the second protection member and the outer frame by double shot molding.

4. The electronic device of claim 1, wherein the display further comprises an installation frame, which defines a receiving slot; and a part of the second protection member is received in the receiving slot.

5. The electronic device of claim 1, wherein the second protection member comprises a flange and a supporting strip extending from a bottom edge of the flange; the flange is secured to the outer frame; and a receiving space is cooperatively defined by the flange and the supporting strip, and the display panel is received in the receiving space.

6. The electronic device of claim 5, wherein the flange is substantially perpendicular to the supporting strip; and the supporting strip is secured to the cover.

7. The electronic device of claim 5, wherein a side surface of the display panel abuts the flange, and a bottom surface of the display panel abuts the supporting strip.

8. The electronic device of claim 5, wherein the flange is secured to an inner surface of the outer frame, and a height of the flange is greater than a height of the outer frame.

9. An electronic device, comprising:
a display comprising:
a cover;
a protection module comprising an outer frame, a first protection member, and a second protection member; and
a display panel;
wherein the second protection member comprises a flange and a supporting strip extending from a bottom edge of the flange; the flange is secured to the outer frame; the supporting strip is secured to the cover; the outer frame is secured to the cover; the first protection member is secured to a first side of the outer frame; the second protection member extends out of a second side of the frame and is located between the cover and the display panel, to prevent the display panel from being hit by the cover; and the first protection member and the second protection member are integrated with the outer frame.

10. The electronic device of claim 9, wherein each of the first protection member and the second protection member is made of flexible glue.

11. The electronic device of claim 10, wherein the outer frame is made of plastic, and the first protection member is integrated with the second protection member and the outer frame by double shot molding.

12. The electronic device of claim 9, wherein the display further comprises an installation frame, which defines a receiving slot; and a part of the second protection member is received in the receiving slot.

13. The electronic device of claim 9, wherein a receiving space is cooperatively defined by the flange and the supporting strip, and the display panel is received in the receiving space.

14. The electronic device of claim 9, wherein the flange is substantially perpendicular to the supporting strip.

15. The electronic device of claim 9, wherein a side surface of the display panel abuts the flange, and a bottom surface of the display panel abuts the supporting strip.

16. The electronic device of claim 9, wherein the flange is secured to an inner surface of the outer frame, and a height of the flange is greater than a height of the outer frame.
